(19) United States
(12) Patent Application Publication
(10) Pub. No.: US 2023/0094212 A1
(43) Pub. Date: Mar. 30, 2023

(54) PLASMA ETCH PROCESS FOR FABRICATING HIGH ASPECT RATIO (HAR) FEATURES

(71) Applicant: Tokyo Electron Limited, Minato-ku (JP)

(72) Inventors: Pingshan Luan, Albany, NY (US); Andrew Metz, Albany, NY (US)

(21) Appl. No.: 17/490,978

(22) Filed: Sep. 30, 2021

(51) Int. Cl. H01L 21/3065; H01L 21/311; H01L 21/02; H01J 37/32

(52) U.S. Cl. CPC H01L 21/3065; H01L 21/31144; H01L 21/31116; H01L 21/0212; H01J 37/32449; H01J 37/32146; H01J 2237/334; H01J 2237/3321

(57) ABSTRACT

A method of processing a substrate that includes: flowing a first unsaturated fluorocarbon, a saturated fluorocarbon, a first noble gas, and dioxygen into a plasma chamber; while flowing these gases, generating a plasma in the plasma chamber; and patterning, with the plasma, a material layer on the substrate.

### TECHNICAL FIELD

The present invention relates generally to a method of plasma processing a substrate, and, in particular embodiments, to a method of fabricating high aspect ratio (HAR) features.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes.

The semiconductor industry has repeatedly reduced the minimum feature sizes in semiconductor devices to a few nanometers to increase the packing density of components. Accordingly, the semiconductor industry increasingly demands plasma processing technology to provide processes for patterning features with accuracy, precision, and profile control, often at atomic scale dimensions. Meeting this challenge along with the uniformity and repeatability needed for high volume IC manufacturing requires further innovations of plasma processing technology.

### SUMMARY

In accordance with an embodiment of the present invention, a method of processing a substrate includes while flowing a first unsaturated fluorocarbon, a saturated fluorocarbon, a first noble gas, and dioxygen into a plasma chamber, generating a plasma in the plasma chamber; and patterning, with the plasma, a material layer on the substrate.

In accordance with an embodiment of the present invention, a method of processing a substrate that includes: flowing, into a plasma chamber, dioxygen (O₂), a first fluorocarbon, and a second fluorocarbon, the first fluorocarbon being unsaturated and the second fluorocarbon being saturated; flowing, into the plasma chamber, a first noble gas and a second noble gas; generating a plasma in the plasma chamber from O₂, the first fluorocarbon, and the second fluorocarbon while flowing the first noble gas and the second noble gas; and etching, with the plasma, a material layer of the substrate using a patterned hardmask layer formed over the material layer as an etch mask.

In accordance with an embodiment of the present invention, a method of forming a high-aspect ratio (HAR) feature on a substrate in a plasma processing chamber, the method including: depositing an amorphous carbon layer (ACL) hardmask over a material layer including silicon oxide formed over the substrate, the substrate including silicon; patterning the ACL hardmask; flowing C₃F₈, C₄F₆, Ar, Kr, and O₂ to the plasma processing chamber; generating a plasma including C₃F₈ and C₄F₆ in the plasma processing chamber while flowing the Ar, Kr, and O₂; and selectively etching the material layer relative to the ACL hardmask and the substrate by exposing the substrate in the plasma processing chamber to the plasma to form the HAR feature.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross sectional views of a substrate during an example process of semiconductor fabrication comprising a plasma etch process to form a high aspect ratio (HAR) feature on the substrate in accordance with various embodiments, wherein FIG. 1A illustrates an incoming substrate comprising a material layer and a patterned hardmask layer, FIG. 1B illustrates the substrate during the formation of the HAR feature by the plasma etch process, and FIG. 1C illustrates the substrate after completing the plasma etch process;

FIGS. 2A-2C illustrate cross sectional views of a substrate after a plasma etch process in accordance with various embodiments with different resulting structures, wherein FIG. 2A illustrates the substrate after the plasma etch process having a clogging issue, FIG. 2B illustrates the substrate after the plasma etch process with a poor selectivity, and FIG. 2C illustrates the substrate after the plasma etch with a poor sidewall passivation;

FIGS. 3A-3C illustrate top views of a substrate after a plasma etch process in accordance with various embodiments with different resulting structures, wherein FIG. 3A illustrates the substrate with a uniform size of opening with a minimal reduction in critical dimension (CD), FIG. 3B illustrates the substrate with widened openings and excess deposition, and FIG. 3C illustrates the substrate with some distorted and uneven openings;

FIGS. 4A-4C illustrate process flow diagrams of methods of semiconductor fabrication comprising a plasma etch process to form HAR features in accordance with various embodiments, wherein FIG. 4A illustrates an embodiment, FIG. 4B illustrates an alternate embodiment, and FIG. 4C illustrates yet another embodiment; and

FIG. 5 illustrates a plasma system for performing a process of semiconductor fabrication in accordance with various embodiments.

### DETAILED DESCRIPTION OF ILLUSTRATIVE EMBODIMENTS

This application relates to fabrication of semiconductor devices, for example, integrated circuits comprising semiconductor devices, and more particularly to high capacity three-dimensional (3D) memory devices, such as a 3D-NAND (or vertical-NAND), 3D-NOR, or dynamic random access memory (DRAM) device. The fabrication of such devices may generally require forming conformal, high aspect ratio (HAR) features (e.g., a contact hole) of a circuit element. Features with aspect ratio (ratio of height of the feature to the width of the feature) higher than 50:1 are generally considered to be high aspect ratio features, and in some cases fabricating a higher aspect ratio such as 100:1 may be desired for advanced 3D semiconductor devices. However, conventional HAR etch methods may usually comprise tens and sometimes hundreds of processing steps, which thereby complicates the process optimization and etch throughput. A simple yet effective HAR process may therefore be desired. Embodiments of the present application disclose methods of fabricating HAR features by a plasma etch process based on a combination of fluorocarbons comprising an unsaturated fluorocarbon and a saturated fluorocarbon. Further, a combination of noble gases may also be included in the plasma etch process for better etch performance.

The methods of plasma etch described in this disclosure may overcome various challenges posed for plasma etching processes for HAR features. In various embodiments, the plasma etch process may advantageously achieve a high AR equal to or higher than 100:1 with a good selectivity to a hardmask. Further, having a good etch rate, this plasma etch process may advantageously be performed in a single step with a shorter process time than a conventional HAR etch method. This feature may improve wafer throughput and the process may be cost-effective. In addition, by tuning the parameters for the additional gases, various methods described in this disclosure may also achieve maintaining the critical dimension (CD) of the hardmask opening and producing straight sidewall profile throughout the whole HAR features.

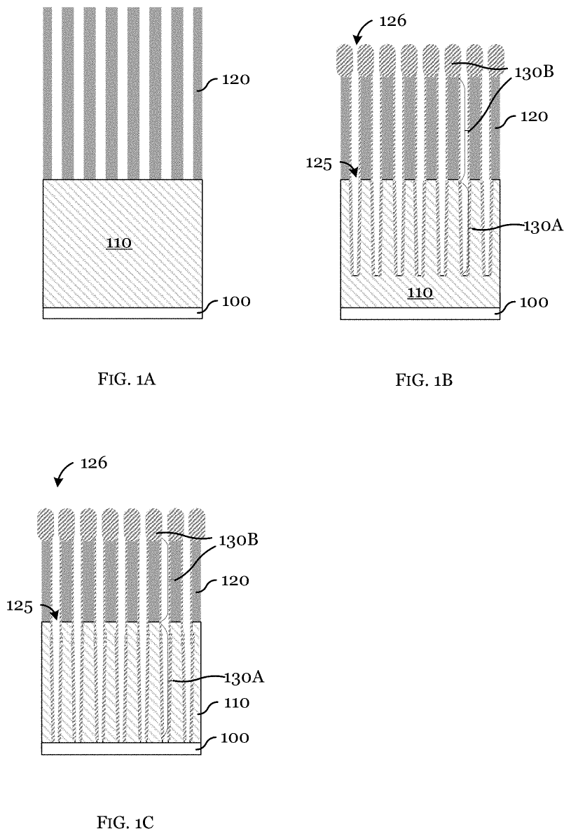

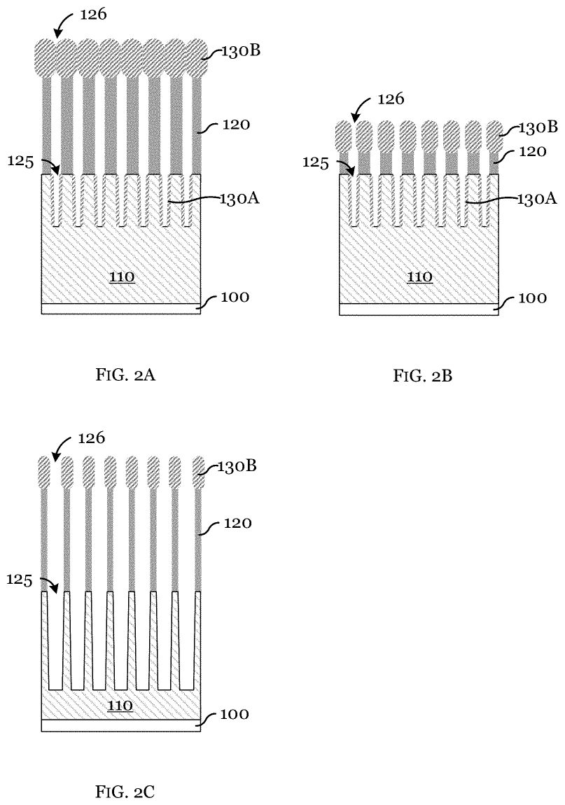

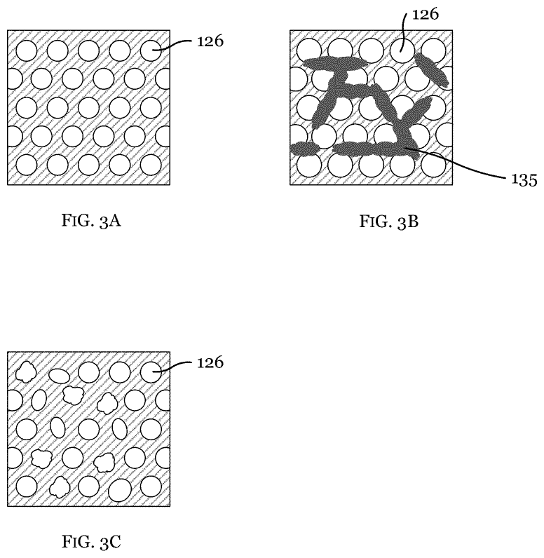

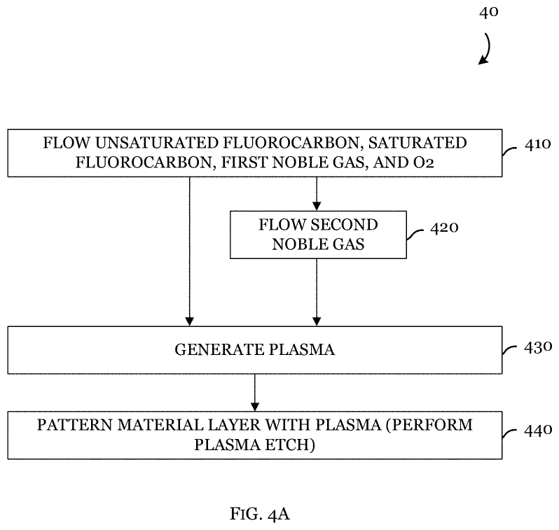

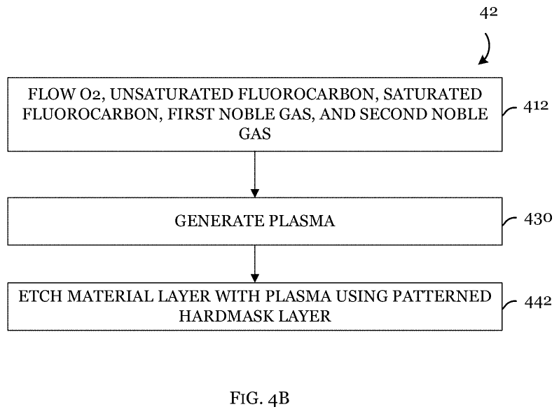

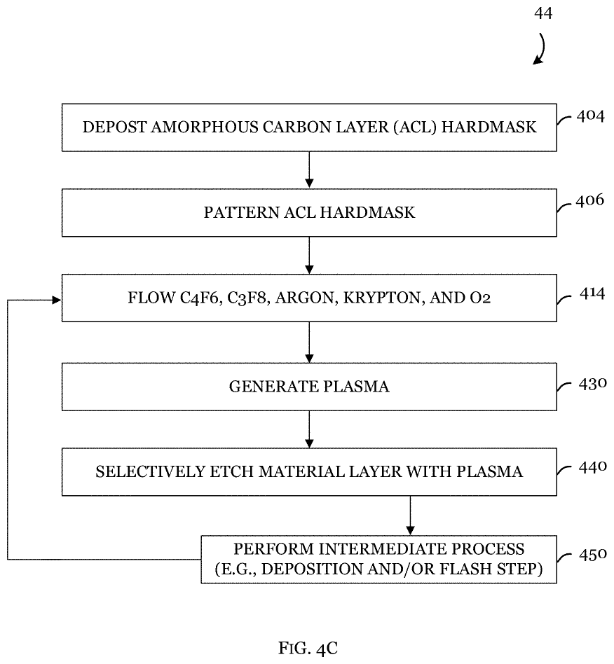

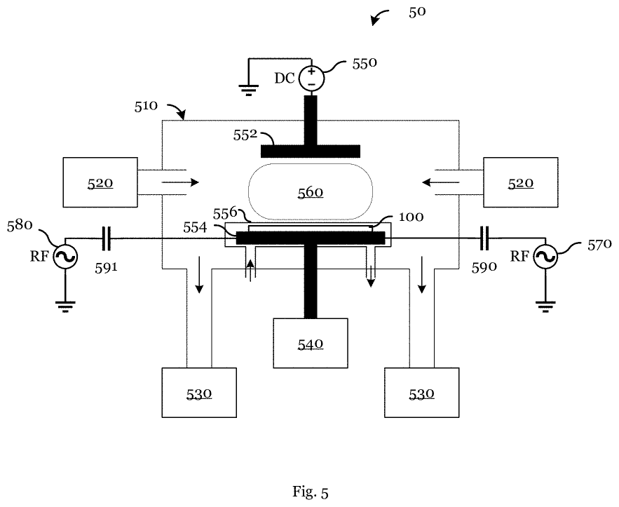

In the following, FIGS. 1A and 1B first illustrates an exemplary plasma etch process to form a desired high aspect ratio (HAR) feature in accordance with various embodiments. The effects on sidewall passivation, selectivity, and critical dimension uniformity (CDU) are described. Next, possible non-ideal resulting structures of features are described referring to FIGS. 2A-2C. These differences of features among different conditions are further described in FIGS. 3A-3C. Example process flow diagrams are then illustrated in FIG. 4A-4C. FIG. 5 provides an example plasma system for performing a process of semiconductor fabrication in accordance with various embodiments. All figures are drawn for illustration purpose only and not to scale.

FIGS. 1A-1C illustrate cross sectional views of a substrate 100 during an example process of semiconductor fabrication comprising a plasma etch process to form a HAR feature on the substrate in accordance with various embodiments.

FIG. 1A illustrates an incoming substrate 100 comprising a material layer 110 and a patterned hardmask layer 120.

In one or more embodiments, the substrate 100 may be a silicon wafer, or a silicon-on-insulator (SOI) wafer. In certain embodiments, the substrate may comprise a silicon germanium wafer, silicon carbide wafer, gallium arsenide wafer, gallium nitride wafer and other compound semiconductors. In other embodiments, the substrate comprises heterogeneous layers such as silicon germanium on silicon, gallium nitride on silicon, silicon carbon on silicon, as well layers of silicon on a silicon or SOI substrate.

In various embodiments, the substrate 100 is a part of a semiconductor device, and may have undergone a number of steps of processing following, for example, a conventional process. For example, the semiconductor structure may comprise a substrate 100 in which various device regions are formed. At this stage, the substrate 100 may include isolation regions such as shallow trench isolation (STI) regions as well as other regions formed therein.

The material layer 110 may be formed over the substrate 100. In various embodiments, the material layer 110 is a target layer that is to be patterned into one or more high aspect ratio (HAR) features. In certain embodiments, the HAR feature being etched into the material layer 110 may be a contact hole, slit, or other suitable structures comprising a recess. In one embodiment, the material layer 110 may be a silicon oxide layer. The material layer 110 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the material layer 110 has a thickness between 1 μm and 10 μm.

Still referring to FIG. 1A, the patterned hardmask layer 120 is formed over the material layer 110. In various embodiments, the patterned hardmask layer 120 may comprise amorphous carbon layer (ACL). The patterned hardmask layer 120 may be formed by first depositing a hardmask layer using, for example, an appropriate spin-coating technique or a vapor deposition technique such as chemical vapor deposition (CVD), physical vapor deposition (PVD), atomic layer deposition (ALD), as well as other plasma processes such as plasma enhanced CVD (PECVD) and other processes. The deposited hardmask layer may then be patterned using a lithography process and an anisotropic etch process. The relative thicknesses of the patterned hardmask layer 120 and the material layer 110 may have any suitable relationship. For example, the patterned hardmask layer 120 may be thicker than the material layer 110, thinner than the material layer 110, or the same thickness as the material layer 110. In certain embodiments, the patterned hardmask layer 120 has a thickness between 1 μm and 4 μm. In one embodiment, the patterned hardmask layer 120 comprises amorphous carbon layer (ACL) and has a thickness of 2.5 μm and a critical dimension (CD) of 75 nm, although in other embodiments, the thickness and the CD of the patterned hardmask layer 120 may have any suitable values, respectively.

The patterned hardmask layer 120 and/or the material layer 110 may be collectively considered as a part of the substrate 100. Further, the substrate 100 may also comprise other layers. For example, for the purpose of patterning the hardmask layer, a tri-layer structure comprising a photoresist layer, SiON layer, and optical planarization layer (OPL) may be present.

Fabricating the HAR feature in the material layer 110 may be performed by a plasma etch process using a combination of gases in accordance with various embodiments. Specifically, two fluorocarbon gases may be used. In various embodiments, the first fluorocarbon may be a unsaturated fluorocarbon and the second fluorocarbon may be a saturated fluorocarbon. In this disclosure, an unsaturated fluorocarbon refers to any compound comprising carbon and fluorine with at least one carbon-carbon double bond (C═C bond) or triple bond (C≡C bond), and a saturated fluorocarbon refers to any compound comprising carbon and fluorine without any C═C bond or C≡C bond. In certain embodiments, the unsaturated fluorocarbon may comprise hexafluorobutadiene (C₄F₆), hexafluoro-2-butyne (C₄F₆), or hexafluorocyclobutene (C₄F₆), and the saturated fluorocarbon may comprise octafluoropropane (C₃F₈), perfluorobutane (C₄F₁₀), or perflenapent (C₅F₁₂). As described more in detail below referring to FIGS. 2A, 2C, and 3B, when only C₄F₆ is used for a plasma etch process, a clogging issue and/or substantial lateral etch (loss of sidewall) in the material layer 110 may occur. The inventors of this application identified that adding C₃F₈, C₄F₁₀, or C₅F₁₂ may advantageously provide significantly better sidewall passivation in high aspect ratio (HAR) recesses formed in the material layer 110, while preventing clogging at the openings of the patterned hardmask layer 120 (e.g., FIG. 1B). In various embodiments, other gases such as a noble gas and/or a balancing agent may also be added. For example, in certain embodiments, argon (Ar) and dioxygen (O₂) may be included as the noble gas and the balancing agent, respectively.

In alternate embodiments, the combination of gases may further comprise a third fluorocarbon. In one embodiment, the third fluorocarbon may be octafluorocyclobutane (C₄F₈), octafluoro-2-butene (C₄F₈), hexafluoropropylene (C₃F₆), carbon tetrafluoride (CF₄), or fluoroform (CHF₃).

Further improvement of the plasma etch process, yet in key process performance metrics other than sidewall passivation, may be achieved by adding a second noble gas in accordance with various embodiments. The second noble gas may be heavier than the first noble gas. Accordingly, the first and second noble gases may be selected from a group of helium (He), neon (Ne), argon (Ar), krypton (Kr), xenon (Xe), and radon (Rn). In certain embodiments, the first noble gas is argon and the second noble gas is krypton. The inventors of this application identified that adding a heavier second noble gas can have a dramatic difference during the etching resulting in improved etch selectivity and critical dimension uniformity (CDU) as further described below referring FIGS. 2B and 3C. Notably, this unique effect is enabled by the combination of two chemically inert gases, instead of flowing two reactive compounds or just flowing any noble gas alone, in a plasma etch process for high aspect ratio (HAR) feature.

Accordingly, the combination of an unsaturated fluorocarbon and a saturated fluorocarbon and the combination of two noble gases may be employed at the same time in various embodiments to optimize the overall plasma etch performance. In certain embodiments, the plasma etch process may use a combination of gases comprising C₄F₆, C₃F₈, Ar, Kr, and O₂. The two combinations can advantageously improve different metrics of process performance, and thereby optimizing the process may be performed by independently tuning each of the combinations as well as a parameter for a balancing agent.

FIG. 1B illustrates the substrate 100 during the formation of the HAR feature by the plasma etch process.

In FIG. 1B, the high aspect ratio (HAR) feature is being formed as recesses 125 in the material layer 110 by the plasma etch process. Generally, the plasma of a plasma etch process for HAR features offers two important species: (i) etchants for removing the target material (e.g., silicon oxide) and (ii) polymerizing radicals to form a polymeric deposition (e.g., sidewall deposition 130A and top deposition 130B), which may be used for sidewall passivation. In various embodiments, gas selection and process parameters may be determined to obtain a desired balance between the two.

As illustrated in FIG. 1B, by the plasma etch process, the recesses 125 may be formed straight and uniformly across the substrate wo with little to no bowing. Bowing refers to the deviation of a perfectly straight recess from a purely anisotropic profile to a recess having outward curvature. Bowing may generally occur near the top of sidewalls of the etch target (e.g., the material layer 110), and may be caused by the bending of incident ion trajectories of ions used during the plasma etching process. Bowing may be eliminated or minimized by the sidewall passivation in the recess 125. Such passivation may be achieved by sidewall deposition 130A of polymerizing radicals extending to the walls of the recesses 125. In various embodiments, the effect of sidewall passivation may be advantageously improved by using a saturated fluorocarbon such as C₃F₈, C₄F₁₀, or C₅F₁₂ as the second fluorocarbon in the plasma etch process.

At the same time, as illustrated in FIG. 1B, such a deposition of polymerizing radicals may also be formed as the top deposition 130B on the hardmask concentrated near openings 126 of the patterned hardmask layer 120. As described below, the top deposition 130B, if in excess, may be detrimental to the etch performance. For example, the amount of the top deposition 130B near the openings 126 may be critical to prevent clogging or maintain the critical dimension (CD) of the HAR feature. In other words, a good balance between the sidewall deposition 130A and the top deposition 130B may need to be realized for the effective etch performance, which may be enabled by various embodiments.

In certain embodiments, the addition of the balancing agent such as dioxygen (O₂) may also be beneficial in this aspect of controlling the amount of deposition. For example, dissociated oxygen species may help controlling the amount of the top deposition 130B, particularly near the openings 126. As a result, clogging may be prevented while the etchants and sidewall passivation species may reach into the recesses 125.

Also in the example of FIG. 1B, a sufficient etch rate enables the recesses 125 to have a high aspect ratio in a short process time compared to conventional HAR etch methods. Simultaneously, due to a good selectivity to the hardmask during the plasma etch process, only a small fraction of the hardmask may be consumed. In certain embodiments, the addition of kypton as the second noble gas may improve the selectivity, which may be due to the increase of the plasma density and CₓF_{y} radicals. In some embodiments, the material layer 110 comprises silicon oxide and the etch selectivity of the silicon oxide may be at least four times greater than that of the hardmask after forming 100:1 aspect ratio contact structures shown in FIG. 1C.

FIG. 1C illustrates the substrate 100 after completing the plasma etch process.

Continuing the plasma etch process, the recesses 125 illustrated in FIG. 1B may be extended further by etching through the entire thickness of the material layer 110 and reach to the top surface of the substrate 100 as illustrated in FIG. 1C. The plasma etch process in accordance with various embodiments may provide a good selectivity to silicon (Si) in addition to the hardmask. Accordingly, the plasma etch may be selective to the substrate 100 comprising silicon and the formation of the recesses 125 may advantageously stop at the top surface of the substrate 100. In certain embodiments, the polymer deposition on the exposed surface of the substrate 100 may advantageously function as an etch stop layer, and such polymer deposition may be improved by species generated from the unsaturated fluorocarbon.

In various embodiments, a RF pulsing at a kHz range may be used to power the plasma. Using the RF pulsing may help generating high energetic ions (>keV) in the plasma for the plasma etch process, while reducing a charging effect. The charging effect during a process is a phenomenon where electrons build charge on insulating materials (e.g., silicon oxide of the materials layer 110) creating a local electric field that may steer positive ions to the sidewalls and cause a lateral etching. Therefore, fine tuning the power conditions of the plasma etch process may also be important to minimize the widening of critical dimension (CD) of the high aspect ratio (HAR) feature. In certain embodiments, a moderate duty ratio between 40% to 80% may be used. In one embodiment, a bias power of 18 kW may be pulsed at a frequency of 5 kHz with a duty ratio of 60%.

In certain embodiments, where C₄F₆ and C₃F₈ are included as the fluorocarbon in the plasma etch process, the C₃F₈:C₄F₆ ratio may be kept within the range of 2:1 to 0.2:1.

In certain embodiments, where argon (Ar) and krypton (Kr) are included as the noble gases in the plasma etch process, the Kr flow rate may be 150 sccm or higher. In one embodiment, the Kr flow rate may be 50 sccm or higher at a pressure between 10 mTorr to 30 mTorr. In one embodiment, the flow rate ratio Kr:Ar may be kept within the range of 0.1:1 to 5:1, for example, between 0.5:1 to 0.95:1 in one embodiment.

In one embodiment, the plasma etch process may be performed at gas flow rates of 90-100 sccm for C₄F₆, 65-75 sccm for C₃F₈, 60-70 sccm for O₂, 340-360 sccm for Ar, and 260-290 sccm for Kr, at a temperature of 10-30° C., and at a pressure of 10-30 mTorr, using a dual-frequency capacitively coupled plasma (CCP) chamber with pulsing capabilities at a high frequency (HF) power of 2000-6000 W, at a low frequency (LF) power at 10000-25000 W, at a pulsing frequency of 1-10 kHz, and at a pulsing duty ratio of 40-80%. With the example conditions above, the HAR feature with a high critical dimension uniformity (CDU) and a good sidewall passivation may be obtained (e.g., FIG. 1B and FIG. 3A).

In certain embodiments, the plasma etch process may be advantageously performed as a continuous process with a process time of 60 min or less to form a high aspect ratio (HAR) feature with an aspect ratio of 100:1 or higher.

In one embodiment, after 30-50 min of a continuous etching process, the plasma etch process may drill through a layer of 6-8 μm silicon oxide (SiO₂) with 20-30% over etch (OE) by sacrificing 1-2 μm of amorphous carbon layer (ACL) hardmask, which yields a SiO₂-to-ACL selectivity between 3:1 to 5:1.

In various embodiments, process parameters may be selected to optimize the characteristics of the high aspect ratio (HAR) feature considering various factors comprising controlled level of deposition, selectivity to the hardmask, sidewall passivation in the HAR feature, and good critical dimension uniformity (CDU) among others.

Characteristics, such as CD and pattern defects of the HAR feature, may be measured using optical techniques such as scatterometry, a scanning electron microscope (SEM), transmission electron microscope (TEM), high-resolution TEM (HR-TEM), scanning probe microscope (SPM), atomic force microscope (AFM), scanning tunneling microscope (STM), or other suitable devices.

The process parameters may comprise gas selection, gas flow rates, pressure, temperature, process time, and plasma conditions such as source power, bias power, RF pulsing conditions. In certain embodiments, advantageously enabled by the combination of fluorocarbons and noble gases, some of the process parameters may be adjusted individually to tune each of the above factors (e.g., controlled level of deposition, selectivity to the hardmask, sidewall passivation in the HAR feature, and good CDU) through experiments. For example, if an existing condition cause a clogging issue, one may increase the gas flow rate of a saturated fluorocarbon such as C₃F₈ and/or a balancing agent such as dioxygen (O₂). In another example, if the existing condition leads to a fast consumption of the hardmask (i.e., a poor selectivity to the hardmask), one may increase the gas flow rate of the unsaturated fluorocarbon such as C₄F₆. In a separate example, if the existing condition results in issues in CDU, one may adjust the Ar and Kr flow rate so that desired radical species and density can be produced. The effect of some of the process parameters on the etch performance are further described below referring to FIGS. 2A-2C and 3A-3C.

Further processing may follow conventional processing, for example, by removing the patterned hardmask layer 120, sidewall deposition 130A and top deposition 130B.

FIGS. 2A-2C illustrate cross sectional views of a substrate 100 after a plasma etch process in accordance with various embodiments with different non-ideal resulting structures.

When one or more of the above important factors for the plasma etch process (e.g., controlled level of deposition, selectivity to the hardmask, sidewall passivation, etc.) are absent, the plasma etch process may lead to different structures as illustrated in FIGS. 2A-2C.

In FIG. 2A, a top deposition 130B of polymerizing radicals is in excess and causes a clogging issue, where the openings 126 of the patterned hardmask layer 120 are completely clogged. Alternately, clogging may occur stochastically and some of the openings 126 may be clogged. The inventors identified that these complete or partial clogging issue may occur when, although not limited to, the plasma etch process uses unsaturated fluorocarbons, for example, C₄F₆ and/or C₄F₈, along with insufficient amount of O₂. Generally, the double bonds, triple bonds, and/or the ring structures in unsaturated fluorocarbons may lead to carbon-rich radicals and facilitate the deposition of polymerizing radicals 130 near the openings 126, thereby narrowing the openings 126 and ultimately leading to clogging. When the openings 126 becomes narrower, the influx of the etchant reaching to the material layer 110 may be impaired. Consequently, as illustrated schematically in FIG. 2A, the etch rate to form the recesses 125 may be lower than the embodiment in FIG. 1B. Once the openings 126 are completely clogged, the etch in this step may not continue as no more etchant may reach to the material layer 110. This issue may be overcome by introducing multiple processing steps such as a flashing step for reopening the clogged hardmask. However, such embodiments may lead to a more complicated process recipe. a longer process time, and potentially loss of selectivity. In contrast, by increasing the O₂ flow rate, or introducing a saturated fluorocarbon such as C₃F₈ as the second fluorocarbon and/or a balancing agent, the clogging may be prevented as illustrated in FIG. 1B. Such an embodiment accordingly enables a continuous etch process and may lead to a better wafer throughput with shorter process time and less process complexity.

In FIG. 2B, the substrate 100 is after the plasma etch process having a poor selectivity to the hardmask. Consequently, only a small portion of the patterned hardmask layer 120 is remaining. The selectivity may be improved by adding a heavier noble gas such as krypton as described in prior embodiments. However, the inventors also identified, that when krypton is used as the only noble gas in the plasma etch process, a clogging issue, either stochastically or uniformly as illustrated in FIG. 2A may occur. Therefore, in various embodiments, two noble gases are simultaneously flowed at a suitable ratio of the gas flow rates to prevent both clogging, lateral etch, and improve CDU as explained in the later context.

Referring to both FIGS. 2A and 2B, due to the poor sidewall passivation and/or the poor selectivity to the hardmask as described above, the plasma etch process may not be capable of forming a high aspect ratio (HAR) feature in a single etch process unlike the embodiment illustrated in FIGS. 1B and 1C. This consequence is schematically illustrated with the recesses 125 in FIGS. 2A and 2B being shallower than those in FIGS. 1B and 1C.

In FIG. 2C, the substrate 100 is illustrated after performing a plasma etch process having a poor sidewall passivation of the recesses 125. In this example, the widening of the openings 126 and/or the recesses 125 may occur due to the effect of lateral etch. At the same time, bowing may also occur and ultimately lead to delamination of the hardmask. Consequently, the HAR feature of the material layer 110 may suffer line wiggling and/or pattern collapse. To avoid such issues, in various embodiments, the sidewall passivation may be improved by using a saturated fluorocarbon such as C₃F₈, C₄F₁₀, or C₅F₁₂ as the second fluorocarbon while preventing a clogging issue illustrated in FIG. 2A.

FIGS. 3A-3C illustrate top views of a substrate 100 after a plasma etch process in accordance with various embodiments with different resulting structures.

In FIG. 3A, the CD of the openings 126 is well preserved with a minimal loss and a critical dimension uniformity (CDU) is high, corresponding to the cross-sectional view illustrated in FIG. 1B. The circularity of the openings 126 is also maintained.

In FIG. 3B, the openings 126 has been widened substantially as a result of insufficient polymer deposition and poor sidewall passivation. Further, ununiform deposition 135 of polymerizing radicals is stochastically located over the patterned hardmask layer. The ununiform deposition 135 may be caused by using only unsaturated fluorocarbons as described referring to FIG. 2A above, and/or the lack of Kr noble gas in the plasma. Similar to FIG. 2A, the ununiform deposition 135 over the patterned hardmask layer may stochastically lead to clogging of the openings 126. As described in the prior embodiments, using both Ar and Kr noble gas, along with or without a saturated fluorocarbon such as C₃F₈ as the second fluorocarbon and/or a balancing agent, the stochastic clogging may be prevented.

In FIG. 3C, the substrate 100 has some distorted and uneven openings 126. In other words, the CDU is low. This scenario may occur when only one noble gas such as krypton is used in the plasma etch process. The CDU may be improved by balancing two noble gas such as argon and krption as described in prior embodiments.

FIGS. 4A-4C illustrate process flow diagrams of methods of semiconductor fabrication comprising a plasma etch process to form a HAR feature on a substrate comprising a material layer in accordance with various embodiments. The process flow can be followed with the figures discussed above (e.g., FIGS. 1A-1C, 3A) and hence will not be described again.

In FIG. 4A, in accordance with some embodiments, a process flow 40 may start with flowing an unsaturated fluorocarbon, a saturated fluorocarbon, and a first noble gas, and dioxygen (O₂) to a plasma processing chamber (block 410). Next, a plasma may be generated (block 430) and perform an plasma etch process to pattern a material layer of a substrate provided in the plasma processing chamber with the plasma (block 440). Alternately, before generating the plasma (block 430), a second noble gas heavier than the first noble gas (block 420) may optionally be flowed to the plasma processing chamber to improve etch selectivity and uniformity while preventing clogging (e.g., FIGS. 1B, 1C, and 3A).

In FIG. 4B, in accordance with alternate embodiments, a process flow 42 may start with flowing O₂, an unsaturated fluorocarbon, a saturated fluorocarbon, a first noble gas, and a second noble gas heavier than the first noble gas to a plasma processing chamber (block 412). The second noble gas may be advantageously added to improve etch selectivity. The following steps may be the same as the above embodiment illustrated in FIG. 4A, which proceeds with generating a plasma (block 430) and etching a material layer of a substrate with the plasma (block 440, e.g., FIGS. 1B, 1C, and 3A).

In FIG. 4C, in accordance with yet other embodiments, a process flow 44 may start with depositing an amorphous carbon layer (ACL) hardmask over a material layer of a substrate (block 404), followed by patterning the ACL hardmask using, for example, a lithography process and an etch process (block 406). Next, a gas mixture comprising C₄F₆, C₃F₈, argon, krypton, and dioxygen (O₂) may be introduced to a plasma processing chamber (block 414). A plasma may then be generated in the plasma processing chamber (block 430) and the material layer may be selectively etched with the plasma (block 440, e.g., FIGS. 1B, 1C, and 3A). In certain embodiments, the process flow 44 may end at this stage, completing a single process. In other embodiments, the plasma etch process may be performed in a cyclic manner, where after the first plasma etch process (e.g., block 440), an intermediate process such as a deposition step (e.g., a step to reinforce the hardmask) or a flash step (e.g., a step to remove excess deposition) may be performed (block 450). After the intermediate process, the process may be repeated from flowing the gas mixture (block 414) for a next cycle of the plasma etch process.

FIG. 5 illustrates an plasma processing system 50 for performing a process of semiconductor fabrication in accordance with various embodiments.

For illustrative purposes, FIG. 5 illustrates a substrate 100 placed on a substrate holder 554 (e.g., a circular electrostatic chuck (ESC)) inside a plasma processing chamber 510 near the bottom. The substrate 100 may be optionally maintained at a desired temperature using a heater/cooler 556 that surrounds the substrate holder 554. The temperature of the substrate 100 may be maintained by a temperature controller 540 connected to the substrate holder 554 and the heater/cooler 556. The ESC may be coated with a conductive material (e.g., a carbon-based or metal-nitride based coating) so that electrical connections may be made to the substrate holder 554.

As illustrated in FIG. 5, the substrate holder 554 may be a bottom electrode of the plasma processing chamber 510. In the illustrative example in FIG. 5, the substrate holder 554 is connected to two RF-bias power sources, 570 and 580 through blocking capacitors 590 and 591. In some embodiment, a conductive circular plate inside the plasma processing chamber 510 near the top is the top electrode 552. In FIG. 5, the top electrode 552 is connected to an DC power source 550 of the plasma processing system 50.

The gases may be introduced into the plasma processing chamber 510 by a gas delivery system 520. The gas delivery system 520 comprises multiple gas flow controllers to control the flow of multiple gases into the chamber. Each of the gas flow controllers of the gas delivery system 520 may be assigned for each of fluorocarbons, noble gases, and/or balancing agents. In some embodiments, optional center/edge splitters may be used to independently adjust the gas flow rates at the center and edge of the substrate 100.

The RF-bias power sources 570 and 580 may be used to supply continuous wave (CW) or pulsed RF power to sustain the plasma, such as a plasma 560. The plasma 560, shown between the top electrode 552 and the bottom electrode (also the substrate holder 554), exemplifies direct plasma generated close to the substrate 100 in the plasma processing chamber 510 of the plasma processing system 50. Etching may be performed by exposing the substrate 100 to the plasma 560 while powering the substrate holder 554 with RF-bias power sources 570, 580 and optionally the top electrode 552 with the DC power source 550.

The configuration of the plasma processing system 50 described above is by example only. In alternative embodiments, various alternative configurations may be used for the plasma processing system 50. For example, inductively coupled plasma (ICP) may be used with RF source power coupled to a planar coil over a top dielectric cover, the gas inlet and/or the gas outlet may be coupled to the upper wall, etc. In various embodiments, the RF power, chamber pressure, substrate temperature, gas flow rates and other plasma process parameters may be selected in accordance with the respective process recipe. In some embodiments, the plasma processing system 50 may be a resonator such as a helical resonator.

Although not described herein, embodiments of the present invention may be also applied to remote plasma systems as well as batch systems. For example, the substrate holder may be able to support a plurality of wafers that are spun around a central axis as they pass through different plasma zones.

Example embodiments of the invention are summarized here. Other embodiments can also be understood from the entirety of the specification as well as the claims filed herein.

Example 1. A method of processing a substrate that includes: while flowing a first unsaturated fluorocarbon, a saturated fluorocarbon, a first noble gas, and dioxygen (O₂) into a plasma chamber, generating a plasma in the plasma chamber; and patterning, with the plasma, a material layer on the substrate.

Example 2. The method of example 1, where the first unsaturated fluorocarbon includes hexafluorobutadiene (C₄F₆), hexafluoro-2-butyne (C₄F₆), or hexafluorocyclobutnene (C₄F₆).

Example 3. The method of one of examples 1 or 2, where the saturated fluorocarbon includes octafluoropropane (C₃F₈), perfluorobutane (C₄F₁₀), or perflenapent (C₅F₁₂).

Example 4. The method of one of examples 1 to 3, where the material layer includes silicon oxide.

Example 5. The method of one of examples 1 to 4, further including, while flowing the first noble gas, flowing a second noble gas that is heavier than the first noble gas.

Example 6. The method of one of examples 1 to 5, where a ratio of a gas flow rate of the first unsaturated fluorocarbon to a gas flow rate of the saturated fluorocarbon is between 2:1 to 0.2:1

Example 7. The method of one of examples 1 to 6, further including flowing a third fluorocarbon.

Example 8. A method of processing a substrate that includes: flowing, into a plasma chamber, dioxygen (O₂), a first fluorocarbon, and a second fluorocarbon, the first fluorocarbon being unsaturated and the second fluorocarbon being saturated; flowing, into the plasma chamber, a first noble gas and a second noble gas; generating a plasma in the plasma chamber from O₂, the first fluorocarbon, and the second fluorocarbon while flowing the first noble gas and the second noble gas; and etching, with the plasma, a material layer of the substrate using a patterned hardmask layer formed over the material layer as an etch mask.

Example 9. The method of example 8, where the material layer includes silicon oxide, and where the patterned hardmask layer includes amorphous carbon layer (ACL).

Example 10. The method of one of examples 8 or 9, where the first noble gas is argon (Ar), and where the second noble gas is krypton (Kr).

Example 11. The method of one of examples 8 to 10, where the first fluorocarbon includes a fluorocarbon with a chemical formula of C₄F₆, and where the second fluorocarbon includes a fluorocarbon with a chemical formula of C₃F₈.

Example 12. The method of example 10, a gas flow rate of Kr is 50 sccm or greater.

Example 13. A method of forming a high-aspect ratio (HAR) feature on a substrate in a plasma processing chamber, the method including: depositing an amorphous carbon layer (ACL) hardmask over a material layer including silicon oxide formed over the substrate, the substrate including silicon; patterning the ACL hardmask; flowing C₃F₈, C₄F₆, Ar, Kr, and O₂ to the plasma processing chamber; generating a plasma including C₃F₈ and C₄F₆ in the plasma processing chamber while flowing the Ar, Kr, and O₂; and selectively etching the material layer relative to the ACL hardmask and the substrate by exposing the substrate in the plasma processing chamber to the plasma to form the HAR feature.

Example 14. The method of example 13, further including applying a pulsed RF bias power to the plasma.

Example 15. The method of example 14, where the pulsed RF bias power has a duty ratio between 40% to 80%.

Example 16. The method of one of examples 13 to 15, where the HAR feature has an aspect ratio (height to width) of 100:1 or greater.

Example 17. The method of one of examples 13 to 16, where the substrate is exposed to the plasma only once.

Example 18. The method of one of examples 13 to 17, where a duration of exposing the substrate to the plasma is less than 60 min.

Example 19. The method of one of examples 13 to 18, further including: performing an intermediate process including a deposition step adding materials on the ACL hardmask and sidewalls of the HAR feature, and repeating the selectively etching and the intermediate process.

Example 20. The method of example 19, where the intermediate process further includes performing a flash step to remove clogged openings of the ACL hardmask.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
while flowing a first unsaturated fluorocarbon, a saturated fluorocarbon, a first noble gas, and dioxygen (O2) into a plasma chamber, generating a plasma in the plasma chamber; and
patterning, with the plasma, a material layer on the substrate.

2. The method of claim 1, wherein the first unsaturated fluorocarbon comprises hexafluorobutadiene (C4F6), hexafluoro-2-butyne (C4F6), or hexafluorocyclobutnene (C4F6).

3. The method of claim 1, wherein the saturated fluorocarbon comprises octafluoropropane (C3F8), perfluorobutane (C4F10), or perflenapent (C5F12).

4. The method of claim 1, wherein the material layer comprises silicon oxide.

5. The method of claim 1, further comprising, while flowing the first noble gas, flowing a second noble gas that is heavier than the first noble gas.

6. The method of claim 1, wherein a ratio of a gas flow rate of the first unsaturated fluorocarbon to a gas flow rate of the saturated fluorocarbon is between 2:1 to 0.2:1.

7. The method of claim 1, further comprising flowing a third fluorocarbon.

8. A method of processing a substrate, the method comprising:
flowing, into a plasma chamber, dioxygen (O2), a first fluorocarbon, and a second fluorocarbon, the first fluorocarbon being unsaturated and the second fluorocarbon being saturated;
flowing, into the plasma chamber, a first noble gas and a second noble gas;
generating a plasma in the plasma chamber from O2, the first fluorocarbon, and the second fluorocarbon while flowing the first noble gas and the second noble gas; and
etching, with the plasma, a material layer of the substrate using a patterned hardmask layer formed over the material layer as an etch mask.

9. The method of claim 8, wherein the material layer comprises silicon oxide, and wherein the patterned hardmask layer comprises amorphous carbon layer (ACL).

10. The method of claim 8, wherein the first noble gas is argon (Ar), and wherein the second noble gas is krypton (Kr).

11. The method of claim 8, wherein the first fluorocarbon comprises a fluorocarbon with a chemical formula of C4F6, and wherein the second fluorocarbon comprises a fluorocarbon with a chemical formula of C3F8.

12. The method of claim 10, a gas flow rate of Kr is 50 sccm or greater.

13. A method of forming a high-aspect ratio (HAR) feature on a substrate in a plasma processing chamber, the method comprising:
depositing an amorphous carbon layer (ACL) hardmask over a material layer comprising silicon oxide formed over the substrate, the substrate comprising silicon;
patterning the ACL hardmask;
flowing C3F8, C4F6, Ar, Kr, and O2 to the plasma processing chamber;
generating a plasma comprising C3F8 and C4F6 in the plasma processing chamber while flowing the Ar, Kr, and O2; and
selectively etching the material layer relative to the ACL hardmask and the substrate by exposing the substrate in the plasma processing chamber to the plasma to form the HAR feature.

14. The method of claim 13, further comprising applying a pulsed RF bias power to the plasma.

15. The method of claim 14, wherein the pulsed RF bias power has a duty ratio between 40% to 80%.

16. The method of claim 13, wherein the HAR feature has an aspect ratio (height to width) of 100:1 or greater.

17. The method of claim 16, wherein the substrate is exposed to the plasma only once.

18. The method of claim 16, wherein a duration of exposing the substrate to the plasma is less than 60 min.

19. The method of claim 13, further comprising:
performing an intermediate process comprising a deposition step adding materials on the ACL hardmask and sidewalls of the HAR feature, and
repeating the selectively etching and the intermediate process.

20. The method of claim 19, wherein the intermediate process further comprises performing a flash step to remove clogged openings of the ACL hardmask.
